(19) United States
(12) Patent Application Publication
(10) Pub. No.: US 2026/0221989 A1
(43) Pub. Date: Jul. 30, 2026

(54) ALGORITHM SELECTION DEVICE, ALGORITHM SELECTION METHOD AND PROGRAM

(71) Applicant: NTT, Inc., Tokyo (JP)

(72) Inventors: Sang-Yuep KIM, Tokyo (JP); Takahiro SUZUKI, Tokyo (JP); Junichi KANI, Tokyo (JP)

(21) Appl. No.: 19/142,658

(22) PCT Filed: Jan. 30, 2023
(86) PCT No.: PCT/JP2023/002783

§ 371 Date: Jun. 24, 2025

(51) Int. Cl. H03M 13/13

(52) U.S. Cl. CPC H03M 13/13

(57) ABSTRACT

An algorithm selection device that selects an algorithm to be used by a calculation unit that performs calculation in a physical layer in data communication on the basis of a use status of a resource in the calculation unit.

### TECHNICAL FIELD

The present invention relates to an algorithm selection device, an algorithm selection method and a program.

### BACKGROUND ART

A physical layer function of a communication service is often implemented by using dedicated hardware such as an ASIC specialized for each service. On the other hand, as a method of flexibly and economically providing a communication service, a method of pooling calculation devices of a network and implementing the physical layer function of a communication service using software has attracted attention.

### Citation List

### Non Patent Document

Non Patent Document 1: L. Peterson, et al, “Central office re-architected as a data center,” IEEE Commun. Mag., vol. 54, no. 10, pp. 96-101, October 2016.
Non Patent Document 2: Chih-Lin I, et al, “Recent Progress on C-RAN Centralization and Cloudification,” IEEE Access, volume 2, pp. 1030-1039, 2014.
Non Patent Document 3: “40-gigabit-capable passive optical networks 2 (NG-PON2): physical media dependent (PMD) layer specification,” ITU-T Recommendation G. 989.2 (2014).

### SUMMARY OF INVENTION

### Technical Problem

In a method in which the physical layer function is implemented by software, when communication traffic of a specific service interface protocol is concentrated, it is conceivable to cope with it by increasing the number of transceivers allocated to the service interface protocol. At this time, the amount of calculation for processing a physical layer communication function of the service interface protocol also increases, but the physical layer communication function performs calculation at a bit level. Therefore, when the amount of calculation in the processor exceeds the computing capability, an error outside an expected value occurs in all output data strings. Therefore, it is difficult to operate the physical layer function in real time using software.

An object of the present invention is to provide an algorithm selection device, an algorithm selection method, and a program that solve the above problems.

### Solution to Problem

An aspect of the present invention is an algorithm selection device that selects an algorithm to be used by a calculation unit that performs calculation in a physical layer on the basis of a use status of a resource in the calculation unit.

An aspect of the present invention is an algorithm selection method including selecting an algorithm to be used by a calculation unit that performs calculation in a physical layer on the basis of a use status of a resource in the calculation unit.

### Advantageous Effects of Invention

In an algorithm selection device, an algorithm selection method, and a program of the present invention, a function in a physical layer in data communication can be operated in real time by software.

### BRIEF DESCRIPTION OF DRAWINGS

FIG. 1 A diagram illustrating an example of a configuration of a communication device 1 according to a first embodiment.

FIG. 2 A diagram illustrating an example of calculation processing of a processor 141 according to the first embodiment.

FIG. 3 A flowchart illustrating an operation of an algorithm selection unit 15.

FIG. 4 A diagram illustrating an example of a configuration of a processor 141 according to a second embodiment.

FIG. 5 A diagram illustrating a modification of the calculation processing of the processor 141.

### DESCRIPTION OF EMBODIMENTS

Hereinafter, an algorithm selection device, an algorithm selection method, and a program according to an embodiment of the present invention will be described with reference to the drawings.

### First Embodiment

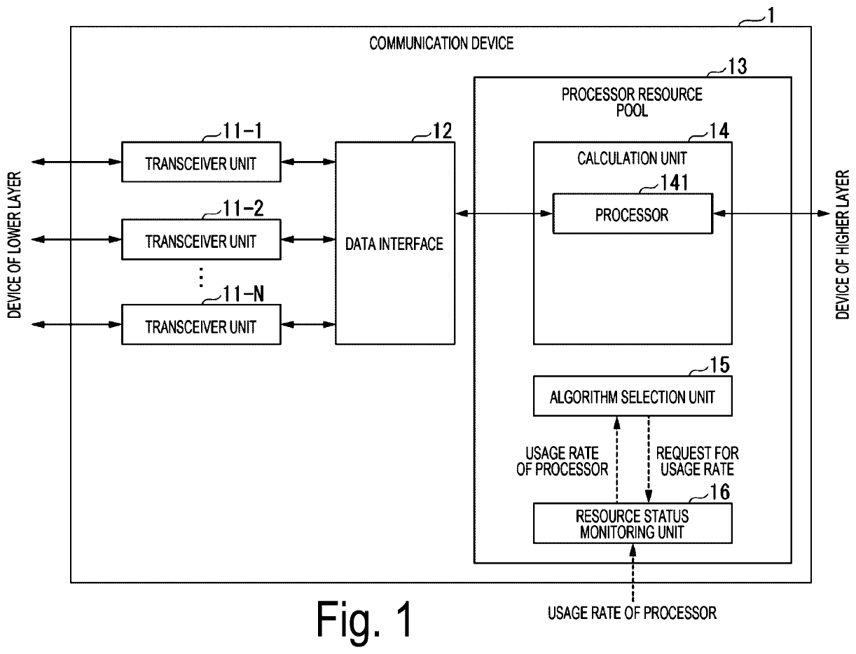

FIG. 1 is a diagram illustrating an example of a configuration of a communication device 1 according to a first embodiment. The communication device 1 performs a function of a physical layer in data communication using a single protocol. The communication device 1 includes a transceiver unit 11, a data interface 12, and a processor resource pool 13. The processor resource pool 13 includes a calculation unit 14, an algorithm selection unit 15, and a resource status monitoring unit 16. The calculation unit 14 includes a processor 141. The processor 141 is a general-purpose processor that does not limit a specific application. Since the general-purpose processor performs calculation on software, the function can be easily changed.

The transceiver unit 11 communicates with a device in a layer lower than the communication device. The communication device 1 includes a plurality of transceiver units 11-1 to 11-N. In the plurality of transceiver units 11-1 to 11-N, the number of transceiver units 11 allocated to the protocol varies according to variation in communication traffic. In a case where the communication device 1 performs optical communication, the number of wavelengths allocated to the protocol is changed according to variation in communication traffic. The number of wavelengths allocated to the protocol corresponds to the number of transceiver units 11 allocated to the protocol. This is implemented by, for example, NG-PON2 disclosed in Non Patent Literature 3. In a case where the communication device 1 performs wireless communication, the number of antennas used for the protocol is changed according to variation in communication traffic. The number of antennas used for the protocol corresponds to the number of transceiver units 11 allocated to the protocol. This is implemented by, for example, MIMO.

The transceiver unit 11 has a transmission function and a reception function. The transceiver unit 11 receives a signal from the device in the lower layer, performs analog-to-digital conversion, and outputs the signal to the data interface 12. In addition, the transceiver unit 11 performs digital-to-analog conversion on a signal input from the data interface 12 and transmits the signal to the device in the lower layer.

In a case where the communication device 1 performs optical communication, the transceiver unit 11 includes a light source, an optical modulation device, an optical local oscillator, and an optical IQ hybrid device. The optical IQ hybrid device converts a multi-level modulated parse band signal into a baseband IQ signal. In a case where the communication device 1 performs wireless communication, the transceiver unit 11 includes a radio wave transmitter, a modulation device, a local oscillator, and an IQ hybrid device. The IQ hybrid device converts a multi-level modulated parse band signal into a baseband IQ signal.

The transceiver unit 11 is connected to the processor 141.

The data interface 12 relays data between the transceiver unit 11 and the processor resource pool 13.

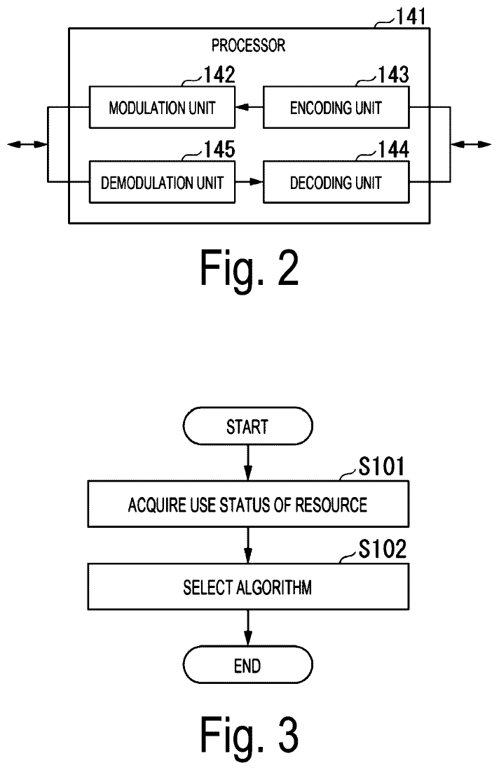

The calculation unit 14 performs calculation in the physical layer in data communication by the included processor 141. FIG. 2 is a diagram illustrating an example of calculation processing of the processor 141 according to the first embodiment. The processor 141 performs calculation using the algorithm selected by the algorithm selection unit 15 described later. The processor 141 includes a modulation unit 142, an encoding unit 143, a decoding unit 144, and a demodulation unit 145. The encoding unit 143 encodes data received from a device in a higher layer, and the modulation unit 142 modulates the data and outputs the data to the data interface 12. In addition, the demodulation unit 145 demodulates data received from the device in the lower layer via the data interface 12, and the decoding unit 144 decodes the data and transmits the data to the device in the higher layer. The modulation by the modulation unit 142, the encoding by the encoding unit 143, the decoding by the decoding unit 144, and the demodulation by the demodulation unit 145 are based on the algorithm selected by the algorithm selection unit 15.

The modulation unit 142 performs, for example, multi-level modulation on data. The demodulation unit 145 performs coherent demodulation on data, for example. The encoding unit 143 and the decoding unit 144 perform, for example, error correction of data in addition to encoding and decoding of data.

The algorithm selection unit 15 selects an algorithm to be used for calculation by the processor 141. The algorithm selection unit 15 selects one algorithm from among a plurality of algorithms having different complexities. The algorithm selection unit 15 selects, for example, an algorithm used by the modulation unit 142 for modulation and by the demodulation unit 145 for demodulation from an algorithm of M-QAM modulation and demodulation with heavy complexity or an algorithm of M-PSK modulation and demodulation with light complexity. The algorithm selection unit 15 selects, for example, an algorithm used by the demodulation unit 145 for demodulation from an algorithm of carrier phase synchronization with heavy complexity or an algorithm of differential detection with light complexity. For example, the algorithm selection unit 15 selects an algorithm used by the encoding unit 143 and the decoding unit 144 for encoding and decoding from an encoding and decoding algorithm based on low density parity check (LDPC) codes with heavy complexity or an encoding and decoding algorithm based on Reed-Solomon (RS) codes having light complexity.

The resource status monitoring unit 16 monitors a use status of a resource in the calculation unit 14. The resource status monitoring unit 16 monitors, for example, a usage rate of the processor 141 as the use status of the resource in the calculation unit 14. The resource status monitoring unit 16 may monitor the calculation time of the algorithm in the processor 141, the number of transceiver units 11 connected to the processor 141, or the temperature of the processor 141 as the usage rate of the processor 141. An increase in the calculation time of the algorithm in the processor 141, an increase in the number of transceiver units 11 connected to the processor 141, and an increase in the temperature of the processor 141 correspond to an increase in the usage rate of the processor 141. A decrease in the calculation time of the algorithm in the processor 141, a decrease in the number of transceiver units 11 connected to the processor 141, and a decrease in the temperature of the processor 141 correspond to a decrease in the usage rate of the processor 141.

For example, the resource status monitoring unit 16 periodically acquires the use status of the resource in the calculation unit 14 and stores the use status of the resource in a storage device. For example, the resource status monitoring unit 16 periodically acquires the usage rate of the processor 141 from an external device (such as a processor driver or a temperature sensor attached to the processor) and stores the usage rate in the storage device.

The algorithm selection unit 15 selects an algorithm on the basis of the use status of the resource in the calculation unit 14 monitored by the resource status monitoring unit 16. When the usage rate of the processor 141 increases and exceeds a predetermined threshold, the algorithm selection unit 15 switches the algorithm used by the processor 141 from an algorithm with high complexity to an algorithm with low complexity. For example, when the usage rate of the processor 141 decreases and becomes lower than a predetermined threshold, the algorithm selection unit 15 switches the algorithm used by the processor 141 from an algorithm with low complexity to an algorithm with high complexity.

The algorithm selection unit 15 acquires the use status of the resource, for example, by requesting the resource status monitoring unit 16 to notify the use status of the resource recorded in the storage device. The resource status monitoring unit 16 returns the usage rate of the processor 141 to the algorithm selection unit 15 in response to a request from the algorithm selection unit 15.

FIG. 3 is a flowchart illustrating an operation of the algorithm selection unit 15. The algorithm selection unit 15 acquires the use status of the resource from the resource status monitoring unit 16 (step S101). The algorithm selection unit 15 selects an algorithm to be used by the processor 141 on the basis of the use status of the resource (step S102).

With the above configuration, the communication device 1 can prevent the occurrence of an error by changing the algorithm when the amount of calculation in the processor 141 exceeds the computing capability, and can operate the physical layer function in real time using software.

### Second Embodiment

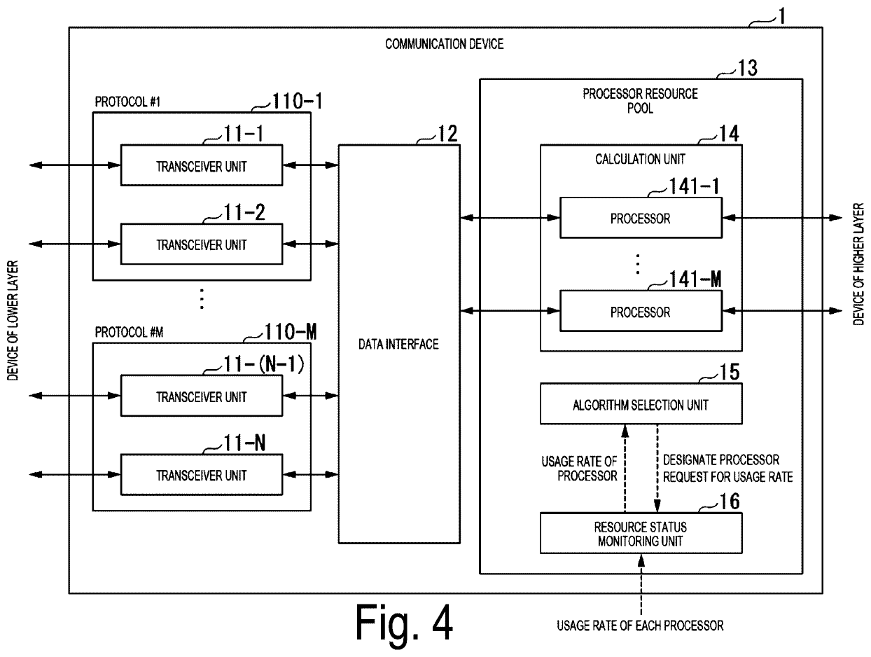

FIG. 4 is a diagram illustrating an example of a configuration of a communication device 1 according to a second embodiment. Unlike the communication device 1 according to the first embodiment, the communication device 1 according to the second embodiment performs a function of a physical layer in data communication using a plurality of protocols. A calculation unit 14 according to the second embodiment is different from the calculation unit 14 according to the first embodiment and includes a plurality of processors 141-1 to 141-M.

The plurality of transceiver units 11 is divided into the same number of transceiver groups 110-1 to 110-M as the number of processors. Transceiver units 11 included in a transceiver group 110 are connected to a corresponding processor 141. For example, the transceiver units 11 included in the transceiver group 110-1 are connected to the corresponding processor 141-1, and the transceiver units 11 included in the transceiver group 110-2 are connected to the corresponding processor 141-2.

An allocated protocol is different for each combination of the processor 141 and the transceiver group 110. The allocated protocol is, for example, a protocol for optical communication or a protocol for wireless communication. Each of the processors 141-1 to 141-M according to the second embodiment operates a physical layer of a protocol. In the plurality of transceiver units 11-1 to 11-N, the number of transceiver units 11 allocated to the protocol varies according to variation in communication traffic. That is, the number of transceiver units 11 included in the transceiver group 110 varies.

The resource status monitoring unit 16 according to the second embodiment monitors the usage rate of each processor 141 as the use status of the resource in the calculation unit 14. The resource status monitoring unit 16 periodically acquires the usage rate of the processor 141 for each processor 141 from an external device (such as a processor driver or a temperature sensor attached to the processor), and records the usage rate of each processor 141 in a storage device.

The algorithm selection unit 15 according to the second embodiment selects an algorithm to be used for calculation by the processor 141 on the basis of the usage rate of each processor 141.

The algorithm selection unit 15 according to the second embodiment designates and requests the processor 141 to notify the resource status monitoring unit 16 of the usage rate of the processor 141 recorded in the storage device, thereby acquiring the usage rate of the designated processor. The resource status monitoring unit 16 returns the usage rate of the processor designated in response to the request of the algorithm selection unit 15 to the algorithm selection unit 15.

### Modification of Processor

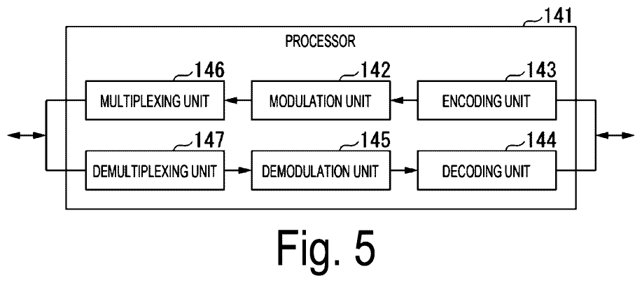

FIG. 5 is a diagram illustrating a modification of the calculation processing of the processor 141. In the modification of the processor 141, the communication device 1 multiplexes data. The modification of the processor 141 includes a multiplexing unit 146 and a demultiplexing unit 147 in addition to the processor 141 according to the first embodiment and the second embodiment. In a modification of the processor 141, the encoding unit 143 encodes data received from the device in the higher layer, the modulation unit 142 modulates the data, and the multiplexing unit 146 multiplexes the data and outputs the data to the data interface 12. Further, the demultiplexing unit 147 demultiplexes data received from the device in the lower layer via the data interface 12, the demodulation unit 145 demodulates the data, and the decoding unit 144 decodes the data and transmits the data to the device in the higher layer.

In a case where the processor 141 includes the multiplexing unit 146 and the demultiplexing unit 147, the algorithm selection unit 15 selects an algorithm to be used by the multiplexing unit 146 and the demultiplexing unit 147. For example, the multiplexing method of the multiplexing unit 146 and the demultiplexing unit 147 is selected from an algorithm of filter-bank multi-carrier modulation (FBMC) with heavy complexity or an algorithm of orthogonal frequency-division multiplexing (OFDM) with light complexity. The algorithm selection unit 15 selects an algorithm to be used by the multiplexing unit 146 and the demultiplexing unit 147 on the basis of the use status of the resource in the calculation unit 14 monitored by the resource status monitoring unit 16.

With the above configuration, the communication device 1 can operate the physical layer function in real time using software even when carrier multiplexing is performed.

At least a part of the function of the processor resource pool 13 may be implemented by a computer. In that case, a program for implementing the functions of the algorithm selection unit 15 and the resource status monitoring unit 16 may be recorded in a computer-readable recording medium, and the program recorded in the recording medium may be read and executed by a computer system to implement the functions. The computer system includes, for example, a processor, an OS, and hardware such as peripheral devices. The program of the processor resource pool 13 may be recorded in a computer-readable recording medium. The computer-readable recording medium is, for example, a portable medium such as a flexible disk, a magneto-optical disk, a ROM, or a CD-ROM or a storage device such as a hard disk built in the computer system. The program of the processor resource pool 13 may be transmitted via a telecommunication line.

Although the embodiments of the present invention have been described in detail with reference to the drawings, specific configurations are not limited to the embodiments and include design and the like within the gist of the present invention.

### REFERENCE SIGNS LIST

1 Communication device
11 Transceiver unit
12 Data interface
13 Processor resource pool
14 Calculation unit
141 Processor
142 Modulation unit
143 Encoding unit
144 Decoding unit
145 Demodulation unit
146 Multiplexing unit
147 Demultiplexing unit
15 Algorithm selection unit
16 Resource status monitoring unit

1. An algorithm selection device, wherein
an algorithm to be used by a calculator that performs calculation in a physical layer in data communication is selected on a basis of a use status of a resource in the calculator.

2. The algorithm selection device according to claim 1, wherein
a use status of the resource in the calculator is a usage rate of a processor that performs calculation in a physical layer.

3. The algorithm selection device according to claim 2, wherein
a plurality of protocols for data communication is allocated to a plurality of the processors, respectively.

4. The algorithm selection device according to claim 2, wherein
the processor is a general-purpose processor that does not limit a specific application.

5. The algorithm selection device according to claim 2, wherein
a usage rate of the processor is periodically acquired and saved, and a usage rate of the processor is returned in response to a request designating the processor.

6. The algorithm selection device according to claim 1, wherein
an algorithm of modulation or demodulation, encoding or decoding, and multiplexing or demultiplexing in the calculator is selected.

7. An algorithm selection method comprising:
selecting an algorithm to be used by a calculator that performs calculation in a physical layer on a basis of a use status of a resource in the calculator.

8. A non-transitory storage medium storing a program for causing a computer to execute the algorithm selection method according to claim 7.
